(19) United States
(12) Patent Application Publication
(10) Pub. No.: US 2020/0358418 A1
(43) Pub. Date: Nov. 12, 2020

(54) MICROWAVE GENERATION

(71) Applicant: Teledyne UK Limited, Chelmsford Essex (GB)

(72) Inventors: Mark ISKANDER, Chelmsford, Essex (GB); David ROWLANDS, Chelmsford, Essex (GB)

(73) Assignee: Teledyne UK Limited, Chelmsford Essex (GB)

(21) Appl. No.: 16/754,641

(22) PCT Filed: Oct. 10, 2018
(86) PCT No.: PCT/GB2018/052896

§ 371 Date: Apr. 9, 2020

(30) Foreign Application Priority Data
Oct. 10, 2017 (GB) 1716593.7

(51) Int. Cl. H03H 7/38; H03K 3/57; H01J 25/587

(52) U.S. Cl. CPC H03H 7/38; H01J 25/587; H03K 3/57

(57) ABSTRACT

A microwave generation system comprising a microwave generator, a pulse generator and an impedance network. The pulse generator is arranged to provide pulses of electrical power to the microwave generator and is operable to vary the power of the pulses of electrical power which are provided to the microwave generator. The impedance network is connected between the pulse generator and the microwave generator. The impedance network is switchable so as to substantially match an impedance across the pulse generator according to variations in the impedance of the microwave generator.

### FIELD OF THE INVENTION

The present disclosure relates to apparatus and methods for the generation of microwaves. The apparatus and methods may find particular application but not exclusively in the field of the generation of microwaves for use in a particle accelerator.

### BACKGROUND

A microwave generator such as a magnetron or a klystron may be used to generate microwaves for a variety of different purposes. For example, microwaves generated by a microwave generator may be provided to a particle accelerator (such as a linear accelerator) and used to establish accelerating electromagnetic fields for the acceleration of charged particles, such as electrons. In some applications accelerated electrons may be directed to be incident on a target material (such as tungsten), which causes some of the energy of the electrons to be emitted as x-rays from the target material.

Generated X-rays may, in some applications, be used for medical imaging and/or treatment purposes. For example, x-rays may be directed to be incident on all or part of a patient's body and one or more sensors may be positioned to detect x-rays which are transmitted and/or reflected by the patient's body. Detected x-rays may be used to form an image of all or part of a patient's body which may be capable of resolving details of the internal structure of the body. X-rays may additionally or alternatively be directed to be incident on a particular part of a patient's body for treatment purposes. For example, x-rays may be directed to be incident on a tumour detected in the body in order to treat the tumour by destroying cancerous cells in the tumour.

Alternatively, accelerated electrons may be directed to be incident on a particular part of a patient's body (such as a tumour) for treatment purposes. For example, electrons output from a particle accelerator (such as a linear accelerator) may be collimated and directed to be incident on part of a patient's body. In some applications, the same apparatus may be used to generate x-rays for imaging and/or treatment purposes and to accelerate electrons for treatment purposes. For example, a target material may be placed in the path of a beam of accelerated electrons output from a particle accelerator in order to generate x-rays and may be removed from the electron beam path in order to use the electron beam for treatment purposes.

In further applications a particle accelerator may be used to generate x-rays for non-medical purposes. For example, generated x-rays may be directed to be incident on a non-medical target to be imaged. One or more sensors may be positioned to detect x-rays which are transmitted by and/or reflected from the imaging target. The detected x-rays may be used to form an image capable of resolving the internal structure of the imaging target. X-ray imaging may find particular use in security related applications, since it is capable of resolving items which are otherwise concealed from view. For example, x-ray imaging may be used to image cargo from outside of a container in which the cargo is stored. X-ray images may be capable of resolving different objects which form part of the concealed cargo in order to identify the contents of the cargo.

Several applications of a microwave generator have been described above in which energy from generated microwaves is used to accelerate charged particles, such as electrons. In some applications it may be desirable to vary the energy of the accelerated particles. For example, in applications in which accelerated electrons are directed to be incident on a target material, thereby causing the emission of x-rays, it may be desirable to vary the energy of the emitted x-rays. This may be achieved by varying the energy to which electrons are accelerated to before being incident on the target material.

Varying the energy of generated electrons may be particularly useful, for example, in applications in which the same apparatus is used to accelerate electrons for medical imaging and treatment purposes. For example, as was described above, the same apparatus may be used to generate x-rays to be used for medical imaging purposes and medical treatment purposes. In general, x-rays to be used for medical imaging purposes may be of lower energy than x-rays to be used for medical treatment purposes. A medical imaging apparatus may, for example, generate x-rays having a first energy in order to image a region of a patient's body. The generated images may then be used to locate a target object (such as a tumour) in the patient's body for treatment in order to guide treatment of the target object. X-rays having a second energy, greater than the first energy, may then be generated and directed to be incident on the target object in the patient's body in order to deliver a treatment dose to the target object.

In other applications, such as the use of x-rays to image non-medical targets such as cargo, it may also be desirable to vary the energy of generated x-rays. For example, a first pulse of x-rays having a first energy may be directed to be incident on an imaging target followed by a second pulse of x-rays having an energy different to the first pulse. The transparency and/or reflectivity of a material to x-rays of varying energy may be different for different materials. Imaging a target using x-rays of varying energy may therefore allow different materials which form the imaging target to be more effectively resolved, when compared to imaging the target using x-rays of a single energy. The use of x-rays of variable energy to image a target may therefore allow concealed objects in the target to be more effectively resolved and identified.

Typically, the energy to which particles, such as electrons, are accelerated by a particle accelerator may be varied by varying the strength of accelerating electromagnetic fields which are established in the accelerator. The strength of the accelerating electromagnetic fields may be varied by varying the power of microwaves provided to the particle accelerator by a microwave generator. It may therefore be desirable to vary the power of microwaves output by a microwave generator.

Whilst applications have been described above in which it may be desirable to vary the power of microwaves provided to a particle accelerator, there may be other applications of a microwave generator which do not involve providing microwaves to a particle accelerator. In such applications it may still be desirable to be able to vary the power of the microwaves generated by the microwave generator.

### SUMMARY OF THE INVENTION

A microwave generator such as a magnetron or a klystron typically receives pulses of electrical power and uses the received power to generate microwaves, the energy of the microwaves being dependent, at least in part, on the power of the received pulses of electrical power. The power of microwaves generated by a microwave generator may therefore be varied by varying the power of electrical pulses provided to the microwave generator.

Pulses of electrical power are typically provided to a microwave generator by a power modulator including a pulse generator. The power output of a modulator may be varied in order to vary the power provided to a microwave generator. However, a modulator and a microwave generator are typically optimised for operation at a single operating power level. Reducing or increasing the power which is provided to the microwave generator away from the operating power level for which the modulator and microwave generator are optimised, can lead to disadvantageous effects which degrade the quality of the microwaves output from the microwave generator and/or cause instabilities in the operation of the microwave generator.

It has been found that stable operation of a microwave generator may be achieved by providing a variable impedance across the pulse generator. According to aspects of the invention the impedance across the pulse generator may be varied so as to substantially match the impedance across the pulse generator to the impedance of the microwave generator at different operating power levels of the microwave generator. According to a first aspect of the invention there is provided a microwave generation system comprising: a microwave generator; a pulse generator arranged to provide pulses of electrical power to the microwave generator, wherein the pulse generator is operable to vary the power of the pulses of electrical power which are provided to the microwave generator; and an impedance network connected between the pulse generator and the microwave generator, wherein the impedance network is switchable so as to substantially match an impedance across the pulse generator according to variations in the impedance of the microwave generator.

By substantially matching the impedance across the pulse generator according to variations in the impedance of the microwave generator, any deteriorations in the shape of the pulses of electrical power provided to the microwave generator are advantageously reduced. Providing a switchable impedance network allows for any pulse deterioration to be reduced at a plurality of different operating points (positions on a microwave generator's performance chart) and output powers. The switchable impedance network may therefore improve a dynamic range over which the microwave generator can be efficiently and stably operated. This may be particularly advantageous in applications in which the microwave generator is operated at different power levels as the impedance of the magnetron may be different at different operating points (and output power levels) of the magnetron. The switchable impedance network may be used to substantially match the impedance across the pulse generator at a plurality of different output power levels.

Additionally or alternatively the switchable impedance network may be used to vary the impedance across the pulse generator so as to compensate for any changes in impedance of one or more components of the microwave generation system over time. For example, over the lifetime of the microwave generator the impedance of the microwave generator at a given operating point may change. In such a situation a switchable impedance network may be used to change the combined impedance of the impedance network and the microwave generator so as to substantially match the combined impedance to the impedance of the pulse generator.

Matching the impedance of the microwave generator at different operating power levels may comprise varying the impedance across the pulse generator such that the combined impedance of the microwave generator and the impedance network is substantially matched to the impedance of the pulse generator. References made herein to a first impedance (e.g. the combined impedance of the microwave generator and the impedance network) being substantially matched to a second impedance (e.g. the impedance of the pulse generator) may be interpreted to mean that the difference between the first and second impedances is not greater than about 10% of the first impedance.

The microwave generator may be operable to generate microwaves having powers greater than about 800 kW. The microwave generator may be operable to generate microwaves having powers of less than about 10 MW. In some embodiments, the microwave generator may be operable to generate microwaves having peak powers of greater than about 100 kW. The microwave generator may be operable to generate microwaves having peak powers of less than about 50 MW.

The microwave generator may be operable to generate microwaves having frequencies in the S band (about 2 to 4 GHz), the C band (about 4 to 8 GHz) and/or the X Band (about 8 to 12 GHz). In some embodiments the microwave generator may be operable to generate microwaves having frequencies greater than about 3 GHz. The microwave generator may be operable to generate microwaves having frequencies of less than about 12 GHz.

In some embodiments the microwave generator may be operable to generate microwaves which are suitable for use in imaging applications (e.g. medical imaging). For example, the microwave generator may be operable to generate microwaves which are suitable for driving an electron accelerator to accelerate electrons for generation of x-rays having a power suitable for imaging (e.g. medical imaging) purposes. In such embodiments, the microwave generator may be operable to generate microwaves which have powers which are greater than about 300 kW. The microwave generator may be operable to generate microwaves having powers which are less than about 1.5 MW.

In some embodiments the microwave generator may be operable to generate microwaves which are suitable for use in medical treatment applications. For example, the microwave generator may be operable to generate microwaves which are suitable for driving an electron accelerator to accelerate electrons for generation of x-rays having a power suitable for medical treatment purposes. Additionally or alternatively, the microwave generator may be operable to generate microwaves which are suitable for driving an electron accelerator to accelerate electrons having a power suitable for electron beam therapy purposes. In such embodiments, the microwave generator may be operable to generate microwaves which have powers which are greater than about 1.5 MW. The microwave generator may be operable to generate microwaves having powers which are less than about 10 MW.

In some embodiments the microwave generator may be operable to generate microwaves which are suitable for use in imaging applications such as the imaging of cargo. For example, the microwave generator may be operable to generate microwaves which are suitable for driving an electron accelerator to accelerate electrons for generation of x-rays having a power suitable for cargo imaging and/or scanning purposes. In such embodiments, the microwave generator may be operable to generate microwaves which have powers which are greater than about 300 kW. The microwave generator may be operable to generate microwaves having powers which are less than about 10 MW.

The microwave generator may comprise a magnetron. The microwave generator may comprise one or more of a magnetron, a klystron, a betatron, a gyrotron, a microtron or other form of microwave generator.

The microwave generation system may include a transmission path extending between the pulse generator and the microwave generator and wherein the impedance network is connected between the transmission path and electrical ground.

The impedance network may be arranged to provide a plurality of electrical pathways between the transmission path and electrical ground, wherein at least one of the electrical pathways includes a switch operable to be opened and closed so as to disconnect and connect the pathway so as to vary the impedance between the transmission path and electrical ground.

The switch may be arranged to provide connection and disconnection of an open circuit or short circuit. Connecting and/or disconnecting an open circuit or short circuit may connect or disconnect an electrical pathway so as to change the impedance between the transmission path and electrical ground.

The impedance network may include a plurality of capacitors and a switch arranged such that when the switch is open a first subset of the capacitors is connected across the pulse generator and when the switch is closed a second subset of the capacitors is connected across the pulse generator.

The impedance network may include a plurality of capacitors connected between the transmission path and electrical ground and a switch connected across at least one of the capacitors, wherein the switch is operable to be opened and closed in order to disconnect and connect a short circuit around the at least one capacitor.

A switch which is arranged to disconnect and connect a short circuit around at least one capacitor so as to change a capacitance connected across the pulse generator may be exposed to a smaller voltage than a switch which is arranged directly in an electrical pathway including at least one capacitor. Such an arrangement may therefore allow a switch having a lower voltage rating to be used. This may, for example, allow a switch capable of relatively fast response (such as, for example, a semiconductor switch) to be used as opposed to a relatively slow response switch (such as a relay switch) having a higher voltage rating.

The transmission path may include a pulse transformer and/or inductive adder.

The impedance network may be connected to the transmission path between the microwave generator and the pulse transformer and/or inductive adder.

The impedance network may be connected to the transmission path between the pulse generator and the pulse transformer and/or inductive adder.

The microwave generator may include a magnet.

The magnet may comprise a permanent magnet.

The magnet may comprise an electromagnet operable to vary a magnetic field strength of the electromagnet so as to vary the power of microwaves generated by the microwave generator.

The impedance network may be arranged to vary the impedance across the pulse generator in response to a variation in the magnetic field strength of the magnet.

The microwave generation system may, for example, include a controller capable of detecting a magnetic field strength associated with the magnet. The controller may, for example, receive one or more measurements of the magnetic field strength (e.g. obtained by one or more sensors). Additionally or alternatively the controller may monitor the state of an electromagnet such as a setting of the electromagnet and/or a control signal received by the electromagnet. The controller may control the impedance network in response a variation in the magnetic field strength.

The impedance network may include at least one electronic switch operable to be opened and closed so as to vary the impedance across the pulse generator.

The electronic switch may, for example, comprise a thyrathron, tetrode, triode and/or a semiconductor switch.

The at least one electronic switch may comprise a semiconductor switch.

An electronic switch such as a semiconductor switch may be capable of a relatively fast response. This may be useful in applications in which the output power of the microwave generator is switched on relatively short timescales. For example, in some applications the output power of the microwave generator may be switched on a pulse-to-pulse basis. A switch capable of a relatively fast response such as an electronic switch may be capable of switching the impedance network fast enough to match the changes in output power of the microwave generator.

The semiconductor switch may comprise a solid state field effect transistor (FET) or an insulated-gate bipolar transistor (IGBT).

The impedance network may include at least one relay switch operable to be opened and closed so as to vary the impedance across the pulse generator.

A relay switch may be capable of withstanding relatively high voltages across the switch. A relay switch may therefore be used in relatively high voltage applications.

The microwave generator may be operable to generate microwaves having a first output power in response to receiving pulses of electrical power having a first input power and to generate microwaves having a second output power in response to receiving pulses of electrical power having a second input power.

The microwaves having the first output power may be suitable for driving an electron accelerator to accelerate electrons for generation of x-rays having a power suitable for medical imaging purposes.

The first output power may, for example, be greater than about 300 kW. The first output power may, for example, be less than about 1.5 MW.

The microwaves having the second output power may be suitable for driving an electron accelerator to accelerate electrons having a power suitable for medical treatment purposes.

The second output power may, for example, be greater than about 1.5 MW. The second output power may, for example, be less than about 10 MW.

The impedance network may be switchable so as to vary an impedance across the pulse generator between three or more different impedance values.

The microwave generator may be operable to generate microwaves suitable for driving an electron accelerator to accelerate electrons for generation of x-rays.

According to a second aspect of the invention there is provided a microwave generation apparatus comprising: a microwave generator arranged to receive pulses of electrical power from a pulse generator and use the received power to generate microwaves; and an impedance network arranged to provide an impedance across the pulse generator, wherein the impedance network is switchable so as to vary the impedance across the pulse generator according to variation in the power of the pulses of electrical power received from the pulse generator.

According to a third aspect of the invention there is provided a pulse generation apparatus comprising: a pulse generator arranged to output pulses of electrical power to a microwave generator; and an impedance network arranged to provide an impedance across the pulse generator, wherein the impedance network is switchable so as to vary the impedance between across the pulse generator according to a variation in the power of the pulses of electrical power output from the pulse generator.

According to a fourth aspect of the invention there is provided an impedance network suitable for use in a microwave generation system according to the first aspect, a microwave generation apparatus according to the second aspect or a pulse generation apparatus according to the third aspect.

The impedance network may be switchable between a first impedance suitable for a first operating point of the microwave generator and a second impedance suitable for a second operating point of the microwave generator, wherein the first impedance substantially matches the impedance of the microwave generator to the impedance of the pulse generator at the first operating point of the microwave generator and the second impedance substantially matches the impedance of the microwave generator to the impedance of the pulse generator at the second operating point of the microwave generator.

An operating point of a microwave generator may be associated with a position on a performance chart of the microwave generator. For example, an operating point may denote a peak current and pulse voltage combination which may be associated with a given output power of the microwave generator.

According to a fifth aspect of the invention there is provided an impedance network for a microwave generating system, the impedance network comprising: a first connection for connection to a transmission path extending between a pulse generator and a microwave generator; a second connection for connection to electrical ground; a plurality of capacitors arranged between the first connection and the second connection; and at least one switch arranged to switch at least one of the plurality of capacitors into and out of an electrical pathway between the first connection and the second connection so as to change an impedance between the first connection and the second connection.

The at least one switch may comprise at least one electronic switch.

The at least one switch may comprise at least one relay switch.

According to a sixth aspect of the invention there is provided an electron acceleration system comprising: a microwave generation system according to the first aspect; and an electron accelerator comprising at least one resonant structure arranged to receive electrons from an electron source such that the electrons pass through the resonant structure, wherein the electron accelerator is arranged to receive microwaves generated by the microwave generation system such that the received microwaves establish accelerating electromagnetic fields in the resonant structure, the accelerating electromagnetic fields being suitable for accelerating the electrons travelling through the resonant structure.

According to a seventh aspect of the invention there is provided an x-ray generator comprising: an electron acceleration system according to the sixth aspect; and a target material arranged to receive accelerated electrons output from the electron accelerator and generate x-rays.

According to an eighth aspect of the invention there is provided an x-ray imaging system comprising: an x-ray generator according to the seventh aspect and operable to direct generated x-rays to be incident on an imaging target; and at least one sensor arranged to detect x-rays transmitted by and/or reflected from the imaging target.

According to a ninth aspect of the invention there is provided a radiotherapy system including a microwave generation system according the first aspect, a microwave generation apparatus according to the second aspect, a pulse generation apparatus according to the third aspect, an impedance network according to the fourth aspect, an impedance network according to the fifth aspect, an electron acceleration system according to the sixth aspect, an x-ray generator according to the seventh aspect or an x-ray imaging system according to the eighth aspect.

According to the tenth aspect of the invention there is provided a cargo scanning system including a microwave generation system according the first aspect, a microwave generation apparatus according to the second aspect, a pulse generation apparatus according to the third aspect, an impedance network according to the fourth aspect, an impedance network according to the fifth aspect, an electron acceleration system according to the sixth aspect, an x-ray generator according to the seventh aspect or an x-ray imaging system according to the eighth aspect.

The microwave generator in any preceding aspect may comprise a magnetron.

According to a tenth aspect of the invention there is provided a method of generating microwaves, the method comprising: outputting pulses of electrical power at a pulse generator and providing the pulses of electrical power to a microwave generator so as to cause generation of microwaves at the microwave generator; varying the power of the pulses of electrical power provided to the microwave generator in order to vary the power of the microwaves output by the microwave generator; and varying an impedance across the pulse generator so as to substantially match the impedance across the pulse generator in accordance with a variation in the impedance of the microwave generator.

Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible.

### BRIEF DESCRIPTION OF FIGURES

One or more embodiments of the invention are shown schematically, by way of example only, in the accompanying drawings, in which:

FIG. 1 is a schematic illustration of an x-ray imaging system according to an embodiment of the invention;

FIGS. 2A and 2B are schematic illustrations of a microwave generation system according to an embodiment of the invention;

FIG. 3 is a schematic representation of a performance chart of a magnetron;

FIGS. 4A, 4B and 4C are schematic illustrations of embodiments of an impedance network according to the invention;

FIGS. 5A and 5B are schematic illustrations of further embodiments of an impedance network according to the invention;

FIG. 6 is a schematic illustration of a still further embodiment of an impedance network according to the invention;

FIG. 7 is a schematic illustration of a portion of an embodiment of an impedance network according to the invention;

FIG. 8 is a schematic illustration of a portion of a further embodiment of an impedance network according to the invention;

FIG. 9 is a flow chart of a method of design of an impedance network according to the invention;

FIG. 10 is a schematic illustration of a radiotherapy system according to an embodiment of the invention; and

FIG. 11 is a schematic illustration of a cargo scanning system according to an embodiment of the invention.

### DETAILED DESCRIPTION

Before particular examples of the present invention are described, it is to be understood that the present disclosure is not limited to the particular embodiments described herein. It is also to be understood that the terminology used herein is used for describing particular examples only and is not intended to limit the scope of the claims.

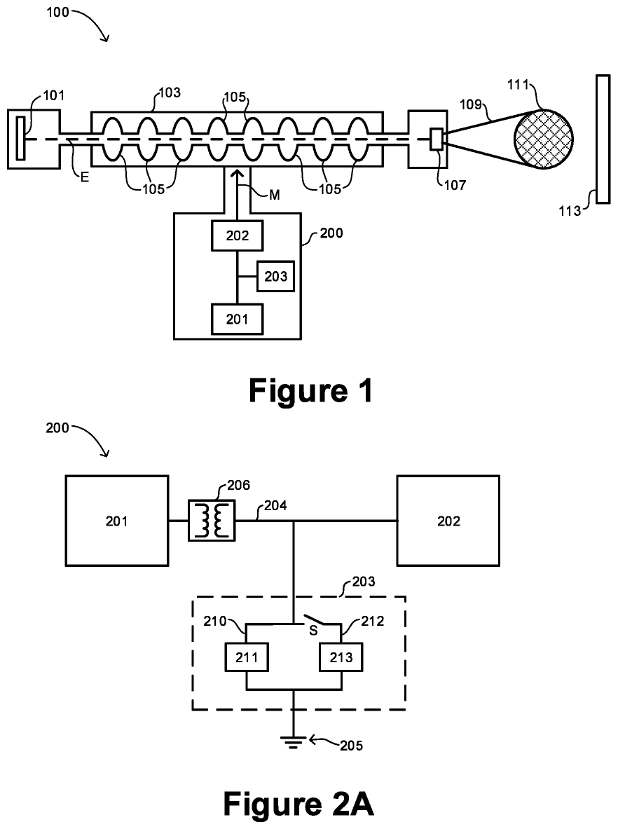

FIG. 1 is a schematic illustration of an x-ray imaging system 100 according to an embodiment of the invention. The x-ray imaging system 100 includes a microwave generation system 200, an electron source 101, an electron accelerator 103, a target material 107 and a sensor 113. The electron source 101 emits an electron beam E which passes through the electron accelerator 103, which in the example shown in FIG. 1 is a linear accelerator (linac). The electron source 101 may, for example, comprise an electron gun.

The accelerator 103 comprises a plurality of resonant structures 105, in the form of cavities 105, arranged to receive the electron beam E from the electron source 101 such that the electron beam E passes through the resonant cavities 105. Whilst in the embodiment which is shown in FIG. 1, the accelerator 103 comprises a plurality of resonant structures 105, in some embodiments an accelerator may only comprise a single resonant structure. For example, in an accelerator such as a microtron, a single resonant structure may be provided and particles, such as electrons, may be passed through the resonant structure several times in order to accelerate the particles.

The accelerator 103 is arranged to receive microwaves M from the microwave generation system 200. As will be explained in further detail below, the microwave generation system 200 comprises a pulse generator 201, a microwave generator 202 and an impedance network 203 connected between the pulse generator 201 and the microwave generator 202. The microwaves M are injecting into the cavities 105 of the accelerator 103 so as to establish accelerating electromagnetic fields in the cavities 105. The accelerating electromagnetic fields act to accelerate the electron beam E as it passes through the accelerator 103.

The target material 107 is arranged to receive the accelerated electron beam E output from the accelerator 103. The target material, which may be a high density material such as tungsten, converts at least some of the energy of the electron beam E to x-rays 109 which are emitted from the target material 107. In the example shown in FIG. 1, the x-rays 109 are directed to be incident on an imaging target 111. The sensor 113 is arranged to detect x-rays 109 which are transmitted through the imaging target and may be configured to form an image of the imaging target 111 based on the detected x-rays. In some embodiments one or more sensors 113 may additionally or alternatively be arranged to detect x-rays which are reflected from the imaging target 111.

The imaging target 111 may, for example, be all or part of a patient's body and x-rays detected by the sensor 113 may be used to form an image which resolves at least part of the internal structure of the patient's body. Alternatively, the imaging target 111 may be a non-medical imaging target 111 such as a container in which cargo is concealed. In such applications the x-rays detected by the sensor 113 may be used to form an image which resolves one or more objects concealed within the container.

Whilst the apparatus which is shown in FIG. 1 has been described as an x-ray imaging system 100, all or part of the apparatus may be used for purposes other than imaging. For example, the microwave generation system 200, the accelerator 103 and the target material 107 together form an x-ray generation system which may be used for purposes other than imaging. For instance, x-rays 109 which are emitted from the target material 107 may be used for medical treatment purposes. Furthermore, the microwave generation system and the accelerator 103 together form an electron acceleration system which may be used for purposes other than the generation of x-rays. For example, in some applications, the target material 107 may be removed from the path of the electron beam E and the electron beam E may itself be used for medical treatment purposes.

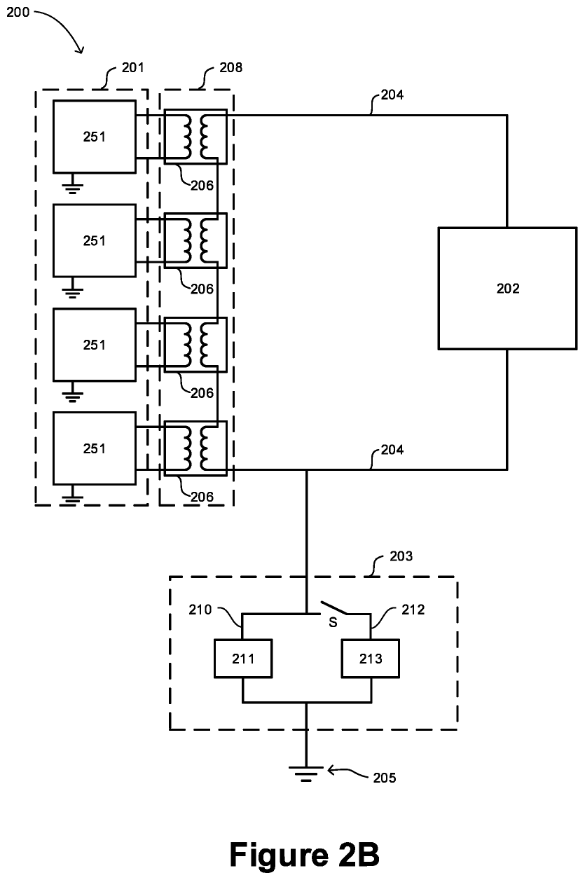

FIG. 2A is a schematic illustration of a microwave generation system 200 according to an embodiment of the invention. As was mentioned above, the microwave generation system 200 comprises a pulse generator 201, a microwave generator 202 and an impedance network 203 connected in between the pulse generator 201 and the microwave generator 202. The microwave generation system 200 further comprises a transmission path 204 extending between the pulse generator 201 and the microwave generator 202 and is arranged to transmit pulses of electrical power output from the pulse generator 201 to the microwave generator 202.

The pulse generator 201 may comprise any components suitable for forming pulses of electrical power. The pulse generator 201 may, for example, comprise a pulse forming network. The pulse generator 201 may comprise one or more charge storage devices such as capacitors which are periodically charged (e.g. by connection to a DC power supply) and discharged so as to output pulses of electrical power.

In the embodiment which is depicted in FIG. 2A, the transmission path 204 includes a pulse transformer 206. The pulse transformer 206 is arranged to step up the voltage of pulses output from the pulse generator 201 so as increase the voltage of the pulses which are provided to the microwave generator 202. The combination of the pulse generator 201 and the pulse transformer 206 may be referred to as a pulse transformer type power modulator, which in practice may be packaged as a single piece of apparatus.

FIG. 2B is a schematic illustration of a microwave generation system 200 according to another embodiment of the invention. In the embodiment which is shown in FIG. 2B the pulse generator 201 is provided in the form of a plurality of pulse generation modules 251. Each pulse generation module 251 may comprise components suitable for forming pulses of electrical power. For example, the pulse generation modules 251 may comprise one or more charge storage devices (such as capacitors) which are periodically charged and discharged (e.g. using a switching circuit) so as to output pulses of electrical power.

The pulse generation modules 251 are connected to primary sides of a plurality of pulse transformers 206. The secondary sides of the pulse transformers 206 are connected to each other to form an inductive adder 208. A transmission path 204 extends between the inductive adder 208 and a microwave generator 202 and is arranged to transmit pulses of electrical power output from the pulse generator 201 (in the form of a plurality of pulse generation modules 251) to the microwave generator 202. Similarly to the embodiment of FIG. 2A an impedance network 203 is connected in between the pulse generator 201 and the microwave generator 202.

The embodiments shown in FIGS. 2A and 2B are provided merely as example embodiments of a microwave generation system 200 including a pulse generator 201, a microwave generator 202 and an impedance network 203. In other embodiments alternative or additional components may be provided to form a microwave generation system 200. The following description of a microwave generation system is applicable to both of the embodiments of FIGS. 2A and 2B and to other embodiments of a microwave generation system comprising a pulse generator 201, a microwave generator 202 and an impedance network 203.

The microwave generator 202 may, for example, comprise a magnetron. In other embodiments the microwave generator 202 may take other forms such as a klystron, a betatron, a gyrotron, a microtron or other form of microwave generator. In general, the microwave generator 202 converts at least some of the energy associated with the pulses of electrical power received from the pulse generator 201 to microwaves.

The microwave generator 202 may be operable to generate microwaves having powers greater than about 300 kW. In some embodiments, the microwave generator 202 may be operable to generate microwaves having powers greater than about 800 kW. The microwave generator 202 may be operable to generate microwaves having powers of less than about 10 MW. In some embodiments, the microwave generator 202 may be operable to generate microwaves having peak powers of greater than about 100 kW. The microwave generator 202 may be operable to generate microwaves having peak powers of less than about 50 MW.

The microwave generator 202 may be operable to generate microwaves having frequencies in the S band (about 2 to 4 GHz), the C band (about 4 to 8 GHz) and/or the X Band (about 8 to 12 GHz). In some embodiments the microwave generator 202 may be operable to generate microwaves having frequencies greater than about 2 GHz. In some embodiments the microwave generator 202 may be operable to generate microwaves having frequencies greater than about 3 GHz The microwave generator 202 may be operable to generate microwaves having frequencies of less than about 12 GHz.

In some embodiments the microwave generator 202 may be operable to generate microwaves which are suitable for use in imaging applications (e.g. medical imaging). For example, the microwave generator 202 may be operable to generate microwaves which are suitable for driving an electron accelerator to accelerate electrons for generation of x-rays having a power suitable for imaging (e.g. medical imaging) purposes. In such embodiments, the microwave generator 202 may be operable to generate microwaves which have powers which are greater than about 300 kW. The microwave generator 202 may be operable to generate microwaves having powers which are less than about 1.5 MW.

In some embodiments the microwave generator 202 may be operable to generate microwaves which are suitable for use in medical treatment applications. For example, the microwave generator 202 may be operable to generate microwaves which are suitable for driving an electron accelerator to accelerate electrons for generation of x-rays having a power suitable for medical treatment purposes. Additionally or alternatively, the microwave generator 202 may be operable to generate microwaves which are suitable for driving an electron accelerator to accelerate electrons having a power suitable for electron beam therapy purposes. In such embodiments, the microwave generator 202 may be operable to generate microwaves which have powers which are greater than about 1.5 MW. The microwave generator 202 may be operable to generate microwaves having powers which are less than about 10 MW.

In some embodiments the microwave generator 202 may be operable to generate microwaves which are suitable for use in imaging applications such as the imaging of cargo. For example, the microwave generator 202 may be operable to generate microwaves which are suitable for driving an electron accelerator to accelerate electrons for generation of x-rays having a power suitable for cargo imaging and/or scanning purposes. In such embodiments, the microwave generator 202 may be operable to generate microwaves which have powers which are greater than about 300 kW. The microwave generator 202 may be operable to generate microwaves having powers which are less than about 10 MW.

All ranges and values (e.g. values and/or ranges of power and/or frequency) are provided for illustrative purposes only and should not be interpreted to have any limiting effect.

Embodiments will be described below in which the microwave generator 202 is realised in the form of a magnetron. However, similar considerations and arrangements may apply in embodiments in which the microwave generator 202 is realised in different forms such as in the form of a klystron, a betatron, a gyrotron, a microtron or other form of microwave generator.

A magnetron 202 comprises a cathode and an anode. A magnet is further provided for generating a magnetic field in between the cathode and the anode. A potential difference is applied between the cathode and the anode. For example, voltage pulses received from the pulse generator 201 are applied across the cathode and the anode to generate a pulsed potential difference between the cathode and the anode. The power of microwaves emitted by the magnetron 202 depend at least in part on the power of the pulses received from the pulse generator 201, and on the strength of the magnetic field generated between the cathode and the anode of the magnetron 202.

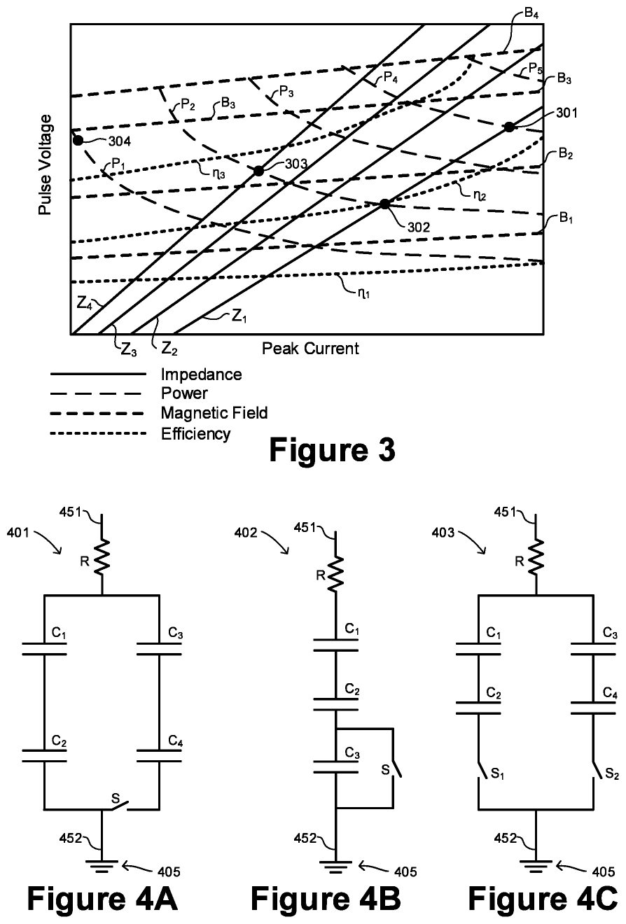

FIG. 3 is a schematic representation of a performance chart of a magnetron 202. The horizontal and vertical axes of the chart shown in FIG. 3 represent a peak current and pulse voltage respectively of pulses of the electrical power provided to the magnetron 202. Each location in the chart of FIG. 3 represents a different current and voltage combination which may be referred to as an operating point of the magnetron 202. The chart of FIG. 3 contains a number of contours which join different operating points at which a given quantity remains constant. The solid lines labelled Z₁, Z₂, Z₃ and Z₄ join operating points at which the impedance of the magnetron is constant and each represent different magnetron impedances Z₁-Z₄ respectively. The dashed lines labelled P₁, P₂, P₃, P₄ and P₅ join operating points at which the output power of the magnetron 202 is constant and each represent different output powers P₁-P₅ respectively. The dash-dot lines labelled B₁, B₂, B₃ and B₄ join operating points at which the magnetic field density between the cathode and the anode of the magnetron 202 is constant and represent different magnetic field densities B₁-B₄ respectively. The dotted lines labelled η₁, η₂ and η₃ join operating points at which the magnetron efficiency is constant and each represent different magnetron efficiencies η₁-η₃ respectively. The efficiency η of the magnetron 202 is the ratio of power output as microwaves to the power input to the magnetron 202.

The labels given to the contours in FIG. 3 represent the relative magnitudes of the various quantities in ascending order. For example, the power represented by the contour labelled P₂ is greater than the power represented by the contour labelled P₁, the power represented by the contour labelled P₃ is greater than the power represented by the contour P₂, the power represented by the contour labelled P₄ is greater than the power represented by the contour labelled P₃ and so on. The same convention applies also for the impedances Z₁-Z₄, the magnetic field densities B₁-B₄ and the efficiencies η₁-η₃.

As was described above, it is often desirable to vary the power of microwaves which are output by the microwave generator 202. As can be seen from FIG. 3 the output power of a magnetron may be varied by changing to a different operating point of the magnetron so as to move between the different power contours P₁-P₅.

The pulse generator 201 is operable to vary the power of the pulses of electrical power which are output from the pulse generator 201 and therefore to vary the pulses of electrical power which are provided to the microwave generator 202. For example, the pulse generator 201 may be operable to vary the voltage of the pulses output from the pulse generator 201 and thereby to vary the voltage of the pulse provided to a magnetron 202.

As can be seen in FIG. 3, varying the pulse voltage which is provided to a magnetron 202 will change the operating point of the magnetron 202 and may be used to vary the output power of the magnetron 202. For example, in principle the voltage of pulses output by the pulse generator 201 and provided to a magnetron 202 could be reduced to reduce the output power of the magnetron from, for instance, the power level P₅ to the power level P₄. However, simply changing the operating point of the magnetron by reducing the voltage of input pulses provided to the magnetron may also change the impedance Z of the magnetron. A change in impedance Z of the magnetron may create an impedance mismatch between the magnetron and the pulse generator 201. An impedance mismatch between the magnetron and the pulse generator 201 may affect the transmission of pulses between the pulse generator 201 and the magnetron, for example, due to power reflections at an impedance mismatch, and may adversely affect the shape of pulses provided to the magnetron 202.

The shape of pulses provided to a magnetron 202 can affect the power and/or frequency of microwaves which are output by the magnetron 202. In general, it may be desirable to provide voltage pulses to a magnetron 202, which have a substantially flat top. That is, the magnitude of the voltage remains substantially constant throughout the duration of the pulse. Variations in the magnitude of the voltage during a voltage pulse can introduce a variation in the frequency of microwaves which are output by the magnetron 202. This may in particular, be disadvantageous when the generated microwaves are used to power a particle accelerator 103 as was described above with reference to FIG. 1. The particle accelerator 103 may have a relatively narrow frequency acceptance band at which microwaves are usefully used to accelerate electrons in the accelerator 103. For example, if the frequency of microwaves provided to the accelerator 103 substantially deviates from the resonant frequency of the cavities 105, then the efficiency with which energy of the microwaves is used to accelerate the electron beam E may significantly decrease.

In general, the efficiency and stability with which a magnetron 202 operates and provides power to a particle accelerator 103 may be substantially degraded by an impedance mismatch between the pulse generator 201 and the magnetron 202.

Referring again to FIG. 3, another way in which the power output of the magnetron 202 may be varied is by varying the magnetic field density B. This may be possible if the magnetron 202 is provided with an electromagnet operable to vary a magnetic field strength generated by the electromagnet. By varying the magnetic field density B in a magnetron 202 it is in principle possible to vary the power output of the magnetron 202 without creating an impedance mismatch between the magnetron 202 and the pulse generator 201. For example, the operating point of the magnetron 202 may be varied along an impedance contour by varying the magnetic field density B in the magnetron 202. One such example, could be to move the operating point of the magnetron 202 between a first operating point 301 shown in FIG. 3 and a second operating point 302 also shown in FIG. 3 along the impedance contour Z₁. In such an example, the output power of the magnetron 202 is reduced from the power P₄ at the first operating point 301 to the power P₂ at the second operating point, without changing the impedance Z₁ of the magnetron 202.

It can be seen in FIG. 3 that moving between the first operating point 301 and the second operating point 302 requires a reduction in the magnetic field density B and in the pulse voltage. Furthermore, any further reduction in the output power of the magnetron 202 whilst remaining on the impedance contour Z₁ would require further reduction in the pulse voltage and magnetic field density B. However, a magnetron 202 may have a limited range of operating points at which stable operation of the magnetron 202 is possible. For example, if the pulse voltage is reduced below a threshold voltage (which may, for example, be about 30 kV) then instabilities in the magnetron 202 operation may occur. Such instabilities might, for example, cause pulses to be missed such that little or no microwave energy is output for a given input voltage pulse.

Changing the output power of a magnetron 202 by varying the magnetic field density in the magnetron 202 and without varying the impedance of the magnetron 202, may therefore only be possible within a limited dynamic range of output powers. Advantageously, the impedance network 203 allows the dynamic power range of the magnetron 202 to be increased without introducing a significant impedance mismatch between the pulse generator 201 and the magnetron 202. The impedance network 203 is switchable so as to vary an impedance across the pulse generator 201. For example, the impedance network 203 may be switchable so as to vary an impedance across the pulse generator 201 according to variation in the power of the pulses of electrical power output by the pulse generator 201.

In the embodiments which are shown in FIGS. 2A and 2B, the impedance network 203 is connected between the transmission path 204 and electrical ground 205. The impedance network 203 is therefore effectively connected across the pulse generator 201 and is switchable so as to vary the impedance between the transmission path 204 and electrical ground 205 so as to vary the impedance across the pulse generator 201.

The impedance network 203 is described herein as being connected between the pulse generator 201 and the microwave generating means. However, it will be appreciated that the impedance network 203 is not connected in series with the transmission path 204 which extends between the pulse generator 201 and the microwave generator 202. References herein to the impedance network 203 being connected between the pulse generator 201 and the microwave generator 202 are merely intended to indicate that the impedance network 203 is connected to a transmission path 204 extending between the pulse generator 201 and the microwave generator 202. The impedance network 203 is connected so as to provide a desired impedance between the pulse generator 201 and the microwave generator 201.

In the embodiments shown in FIGS. 2A and 2B, the impedance network 203 comprises a first electrical pathway 210 between the transmission path 204 and electrical ground 205 and a second electrical pathway 212 between the transmission path 204 and electrical ground 205. The first pathway 210 has a first impedance 211 and the second pathway 212 has a second impedance 213. The second pathway 212 includes a switch S which may be opened and closed in order to disconnect and connect the second pathway 212 so as to vary the impedance between the transmission path 204 and electrical ground 205. When the switch S is open the impedance between the transmission path 204 and electrical ground 205 is determined by the first impedance 211 only. When the switch S is closed the impedance between the transmission path 204 and electrical ground is the parallel combination of the first 211 and second 213 impedances, which is less than the first impedance 211 alone. The switch S may therefore be closed in order to reduce the impedance across the pulse generator 201. The embodiment of the impedance network 203 which is shown in FIGS. 2A and 2B is a simple embodiment provided for illustrative purposes. It will be appreciated that many different embodiments of a switchable impedance network 203 operable to vary the impedance across the pulse generator 201 may be provided, some of which will be described in further detail below.

In some embodiments, the impedance network 203 includes a plurality of capacitors and at least one switch arranged such that when the switch is open a first subset of the capacitors is connected across the pulse generator 201 and when the switch is closed a second subset of the capacitors is connected across the pulse generator 201. The first subset of capacitors may have a different combined capacitance to the second subset of capacitors such that opening and closing the switch changes the capacitance, and the impedance, which is provided by the impedance network 203.

In general, the impedance network 203 is switchable so as to vary an impedance across the pulse generator 201 according to variation in the power of the pulses of electrical power output by the pulse generator 201. For example, the impedance network 203 may be switched such as to vary the impedance across the pulse generator 201 so as to substantially match the impedance of the microwave generator 202 to the impedance of the pulse generator 201 for a given input power of pulses provided to the microwave generator 202. That is, the impedance network 203 may be operable to vary the impedance across the pulse generator 201 such that the combined impedance of the microwave generator 202 and the impedance network 203 is substantially matched to the impedance of the pulse generator 201. By substantially matching the impedance of the microwave generator 202 to the impedance of the pulse generator 201 any deterioration of a voltage pulse shape provided to the microwave generator 202 may be reduced.

References made herein to a first impedance (e.g. the impedance of a microwave generator) being substantially matched to a second impedance (e.g. the impedance of a pulse generator) may be interpreted to mean that the difference between the first and second impedances is not greater than about 10% of the first impedance.

Referring again to FIG. 3 and considering the example of a magnetron 202, the impedance network 203 increases the range of operating points of the magnetron 202 which may be used without causing a significant impedance mismatch which is detrimental to the operation of the magnetron 202. An example, was described above in which the output power of a magnetron 202 can be varied between the power P₄ and the power P₂ by moving between a first operation point 301 and a second operating point 302 which both lie on the impedance contour Z₁. However, with a switchable impedance network 203, the output power P₂ could instead be reached by moving to a third operating point 303. The third operating point 303 lies on the impedance contour Z₄ at which the impedance of the magnetron is greater than the impedance Z₁ at the first 301 and second 302 operating points. In order to prevent a significant impedance mismatch between the pulse generator 201 and the magnetron 202, the impedance network 203 may be switched so as to vary the impedance across the pulse generator 201 during a transition, for instance from the first operating point 301 to the third operating point 303. A switchable impedance network 203 may therefore allow for stable operation of the magnetron 202 at both the first 301 and third 303 operating points without creating a substantial impedance mismatch between the pulse generator 201 and the magnetron 201. That is, any difference in impedance between the pulse generator 201 and the magnetron 201 may be kept within about 10% of the impedances of the pulse generator 201 and/or the magnetron 201.

It can be seen from FIG. 3 that the second 302 and third 303 operating points result in the same output power P₂. However, the third operating point 303 corresponds to a higher pulse voltage than the second operating point 302. As was explained above, operation of a magnetron 202 may become unstable at low pulse voltages and, as such, the stability of magnetron 202 operation may be improved at the third operating point 303 when compared to the second operating point 302. A switchable impedance network 203 may therefore allow a given output power of a magnetron 202 to be reached at an operating point of the magnetron 202 which provides improved operation stability.

Furthermore, a switchable impedance network 203 may allow a dynamic range of output powers which can be provided by a magnetron 202 to be increased. For example, the output power of the magnetron 202 may be further decreased to the power P₁ by moving to a fourth operating point 304. Stable operation of the magnetron 202 at the fourth operating point may be achieved by switching the impedance network 203 to provide an impedance across the pulse generator 201 which substantially matches the impedance of the pulse generator 201 to the magnetron 202 at the fourth operating point 304. The fourth operating point 304 corresponds to a relatively high pulse voltage, when compared, for example, to the second operating point 302 and to an operating point at the first power P₁ and on the impedance contour Z₁. The operating point at the output power P₁ and on the impedance contour Z₁ may, for example, correspond to a pulse voltage which results in unstable operation of the magnetron 202. Stable operation of the magnetron 202 at the output power P₁ may not therefore be possible if operation of the magnetron 202 is restricted to the impedance contour Z₁, whereas a switchable impedance network 203 allows for stable operation of the magnetron 202 at the power P₁ by switching the impedance to allow a greater range of operating points to be used. The switchable impedance network 203 therefore increases a dynamic range of output powers of the magnetron 202 which may be provided during stable operation of the magnetron 202.

Additionally, the switchable impedance network 203 may allow a magnetron 202 to be operated with an improved efficiency η at a given output power of the magnetron 202. For example, the second 302 and third 303 operating points result in the same output power P₂ of the magnetron 202. However the efficiency at the third operating point 303 is greater than the efficiency at the second operating point 302. For a given desired output power, the switchable impedance network 203 may therefore allow the magnetron 202 to be operated at an operating point which provides an improved efficiency by switching the impedance across the pulse generator 201 to match the impedance at the operating point of the magnetron 202.

In the description provided above of different operating points at which a magnetron may be operated with reference to FIG. 3, it was assumed that the magnetic field density B in the magnetron 202 is variable in order to reach different operating points. However, in some embodiments a magnetron 202 may comprise a permanent magnet and as such the magnetic field density B in the magnetron 202 may be fixed. It can be seen from FIG. 3 that if the magnetic field density B of the magnetron 202 is fixed then variations in the output power P of the magnetron 202 are only possible by moving to operating points which result in a variation in the impedance Z. In the absence of a switchable impedance network 203, variations in the output power of a magnetron having a fixed magnetic field density B would therefore result in an impedance mismatch between the pulse generator 201 and the magnetron 202.

A switchable impedance network 203 allows the output power of a magnetron 202 having a fixed magnetic field to be varied without creating an impedance mismatch between the pulse generator 201 and the magnetron 202. For example, the operating point of the magnetron 202 may be varied along a magnetic field density contour and the impedance across the pulse generator 201 may be switched in order to substantially match the impedance of the pulse generator 201 to the impedance of the magnetron 202 at different operating points of the magnetron 202, on the magnetic field density contour.

Advantages of providing a switchable impedance network 203 have been described above in the context of changing the operating point of the magnetron in order to vary the power of microwaves output by the magnetron. Additionally or alternative a switchable impedance network 203 may be used to compensate for changes in the characteristics of one or more components of a microwave generation system 200 over its lifetime. For example, during the useful lifetime of a magnetron, the impedance of the magnetron at a given operating point may change. In such a situation a switchable impedance network 203 may be used to change the combined impedance of the impedance network 203 and the magnetron 202 so as to substantially match the combined impedance to the impedance of the pulse generator 201. For example, if the impedance of the magnetron 202 increases with age, then the impedance network 203 may be switched to provide a lower impedance across the pulse generator 201 so as to substantially match the impedance of the magnetron 202 to the impedance of the pulse generator 201.

In the embodiment which is depicted in FIG. 2A, the impedance network 203 is connected between the pulse transformer 206 and the microwave generator 202. That is, the impedance network 203 is connected to the transmission line 204 in between the pulse transformer 206 and the microwave generator 202. However in other embodiments, the impedance network 203 may be connected to the transmission line 204 between the pulse generator 201 and the pulse transformer 206.

Similarly, whilst in the embodiment which is shown in FIG. 2B the impedance network 203 is connected between the inductive adder 208 and the microwave generator 202, in other embodiments the impedance network may be connected in between the pulse generator 201 and the inductive adder 208.

Typically, a pulse generator 201 and a microwave generator 202 are packaged as separate pieces of apparatus which are capable of connection to form a microwave generation system. A switchable impedance network 203 could be provided as part of a pulse generation apparatus comprising a pulse generator 201 and a switchable impedance network 203. The pulse generation apparatus may further comprise a pulse transformer 206 and/or an inductive adder 208. Additionally or alternatively, a switchable impedance network 203 could be provided as part of a microwave generation apparatus comprising a microwave generator 202 and a switchable impedance network 203. Additionally or alternatively, a switchable impedance network 203 may be provided as a separate piece of apparatus which is suitable for connection to and for use with a microwave generation system 200, a pulse generation apparatus and/or a microwave generation apparatus.

The state of a switchable impedance network 203 may be controlled in response to one or more inputs. For example, the state of one or more switches which form the switchable impedance network 203 may be controlled in response to receiving an input signal. The impedance which is provided by the impedance network 203 may therefore be controlled by sending a control signal (e.g. from a control apparatus) to the impedance network 203. A microwave generation system may be controlled by a control apparatus, which may, for example, control the power (e.g. the pulse voltage) of pulses output by the pulse generator 201, the state (e.g. the connected impedance) of the impedance network 203 and/or the magnitude of the magnetic flux density in the magnetron (e.g. by controlling the state of an electromagnet in the magnetron). A control apparatus could for example, change the operating state and the output power of the magnetron 202 by simultaneously controlling the power output of the pulse generator 201, the state of the impedance network 203 and/or the magnetic flux density in the magnetron 202.

In some embodiments, the state of the impedance network 203 may be responsive to changes in the state of one or more other components. For example, the impedance network 203 may be arranged to vary the impedance across the pulse generator 201 in response to a variation in the magnetic field strength of an electromagnet forming part of the magnetron 202. A change in the magnetic field strength of the electromagnet may be indicative that the operating point of the magnetron 202 is being changed. The impedance network 203 may therefore respond to the change in magnetic field strength by providing an impedance which is suitable for the new operating point of the magnetron. The impedance network 203 may, for example, monitor the strength of the magnetic field generated by the electromagnet and/or may monitor a control signal being input to the electromagnet and may respond to changes in the monitored property. For example, one or more sensors may be provided to monitor the strength of the magnetic field generated by the electromagnet and/or may monitor a control signal being input to the electromagnet. A controller may further be provided to control the impedance network 203 in response to an output provided by the one or more sensors.

An impedance network 203 which is responsive to changes in the state of one or more other components (such as the state of an electromagnet in a magnetron and/or a magnetic field strength in the magnetron) may mean that no additional control infrastructure is required for operation of the impedance network. For example, in embodiments in which the impedance network 203 is responsive to the magnetic field strength in the magnetron 202, the magnetron 202 may be controlled to adjust the magnetic field strength in the magnetron 202, thereby changing the operating state of the magnetron 202. The impedance network 203 may respond to the change in the magnetic field strength in the magnetron 202, without receiving an independent control command. In such embodiments, the impedance network 203 may be packaged and provided with the magnetron 202 to from a microwave generating apparatus comprising the impedance network 203 and the magnetron 202.

FIGS. 4A, 4B and 4C are schematic illustrations of impedance networks according to embodiments of the invention. A first embodiment of an impedance network 401 is shown in FIG. 4A, a second embodiment of an impedance network 402 is shown in FIG. 4B and a third embodiment of an impedance network is shown in FIG. 4C. The first embodiment 401, the second embodiment 402 and the third embodiment 403 are suitable for use in a microwave generation system 200 as described above with reference to FIGS. 2A and 2B.

Each of the first embodiment 401, the second 402 embodiment and the third 403 embodiment of the impedance network includes a first connection 451 and a second connection 452. The first connection 451 is suitable for connection to a transmission path extending between a pulse generator 201 and a microwave generator 202. For example, the first connection 451 may be connected to the transmission path 204 extending between the pulse generator 201 and the microwave generator 203 shown in FIGS. 2A and 2B. The second connection 452 is suitable for connection to electrical ground 405 as shown in FIGS. 4A and 4B. Both embodiments 401, 402 include a resistor R connected in between the first connection 451 and other components of the impedance network. The resistor R may provide a fixed resistance between the first connection 451 and other components of the impedance network 401, 402.

The first embodiment of the impedance network 401, which is shown in FIG. 4A, includes a first capacitor C₁, a second capacitor C₂, a third capacitor C₃ and a fourth capacitor C₄. The first C₁ and second C₂ capacitors are provided in a first electrical pathway extending between the first connection 451 and the second connection 452. The third C₃ and fourth C₄ capacitors are provided in a second electrical pathway extending between the first connection 451 and the second connection 452. The second electrical pathway includes a switch S. The switch S is operable to be opened and closed so as to disconnect and connect the second electrical pathway.

When the switch S is opened, the capacitance and therefore the impedance between the first connection 451 and the second connection 452 is determined by the first C₁ and second C₂ capacitors only. When the switch S is closed, the capacitance and therefore the impedance between the first connection 451 and the second connection 452 is determined by the parallel capacitances and impedances of the first and second electrical pathways. Opening and closing the switch S therefore varies the capacitance and therefore the impedance which is provided between the first 451 and second 452 connections.

The second embodiment of the impedance network 402, which is shown in FIG. 4B, includes a first capacitor C₁, a second capacitor C₂ and a third capacitor C₃ connected in series with each other in between the first connection 451 and the second connection 452. A switch S is connected across the third capacitor C₃. The switch S is operable to be opened in order to include the third capacitor C₃ in the electrical pathway between the first connection 451 and the second connection 452. The switch S is further operable to be closed in order to provide a short circuit around the third capacitor C₃. That is, opening and closing the switch S disconnects and connects a short circuit around the third capacitor C₃.

When the switch S is opened, the capacitance and therefore the impedance between the first connection 451 and the second connection 452 is determined by the series capacitance and impedance of the first C₁, second C₂ and third C₃ capacitors. When the switch S is closed, the capacitance and therefore the impedance between the first connection 451 and the second connection 452 is determined by the series capacitance and impedance of the first C₁ and second C₂ capacitors only, since a short circuit is provided around the third capacitor C₃. Opening and closing the switch S varies the capacitance and therefore the impedance which is provided in between the first 451 and second 452 connections.

The third embodiment of the impedance network 403, which is shown in FIG. 4C, includes a first capacitor C₁, a second capacitor C₂, a third capacitor C₃ and a fourth capacitor C₄. The first C₁ and second C₂ capacitors are provided in a first electrical pathway extending between the first connection 451 and the second connection 452. The third C₃ and fourth C₄ capacitors are provided in a second electrical pathway extending between the first connection 451 and the second connection 452. The first electrical pathway includes a first switch S₁ and the second electrical pathway includes a second switch S₂. The first S₁ and second S₂ switches are operable to be opened and closed so as to disconnect and connect the first and second electrical pathways respectively.

The first S₁ and second S₂ switches S₁ provide three different switching combinations such that the capacitance and impedance provided between the first connection 451 and the second connection 452 may be switched between three different values. For example, if both the first S₁ and second S₂ switches are closed then the capacitance and impedance between the first 451 and second 452 connections is determined by the parallel combination of the first and second electrical pathways. If the first switch S₁ is closed and the second switch S₂ is opened then the capacitance and impedance between the first 451 and second 452 connections is determined by the series combination of the first C₁ and second C₂ capacitors. If the first switch S₁ is opened and the second switch S₂ is closed then the capacitance and impedance between the first 451 and second 452 connections is determined by the series combination of the third C₃ and fourth C₃ capacitors. The impedance network 403 is therefore switchable between three different impedances if the series capacitance of the first C₁ and second C₂ capacitors is different to the series capacitance of the third C₃ and fourth C₄ capacitors.

In the embodiments of an impedance network 401, 402, 403 shown in FIGS. 4A, 4B and 4C the impedance network 401, 402, 403 is switchable between at least a first impedance provided when at least one switch S is open and a second impedance provided when the switch S is closed. The first impedance may be suitable for a first operating point of a microwave generator 203 and the second impedance may be suitable for a second operating point of a microwave generator 203. The first impedance may substantially match the impedance of the microwave generator 203 to the impedance of a pulse generator 201 at the first operating point of the microwave generator 203. The second impedance may substantially match the impedance of the microwave generator 203 to the impedance of the pulse generator 201 at the second operating point of the microwave generator 203.

In one or more of the embodiments 401, 402, 403 at least one of the switches S may be a relay switch such as a vacuum or air relay switch. Typically, voltage pulses which are transmitted from the pulse generator 201 to the microwave generator 202 have a relatively high voltage. For example, the voltage of the pulses may be of the order of about 40 kV. A switch S may therefore be exposed to high voltages during operation. A vacuum or air relay switch can typically withstand high voltages and is therefore suitable for withstanding the voltage levels to which a switch S may be exposed during operation.

In embodiments in which a microwave generation system 200 provides microwaves to a particle accelerator 103 for medical imaging and/or treatment purposes the impedance network 401, 402, 403 may switch between different impedance levels relatively infrequently. For example, the microwave generator 202 may be operable to generate microwaves having a first output power suitable for driving an electron accelerator 103 to accelerate electrons for generation of x-rays having a power suitable for medical imaging purposes. The impedance network 401, 402 may be switched to a first state (e.g. a switch S is opened) to provide a first impedance during generation of microwaves having the first output power. The microwave generator 202 may be further operable to generate microwaves having a second output power suitable for driving an electron accelerator 103 to accelerate electrons for medical treatment purposes. The impedance network 401, 402, 403 may be switched to a second state (e.g. a switch S is closed) to provide a second impedance during generation of microwaves having the second output power.

The microwave generator 202 may only switch between operation at the first power level and operation at the second power level once or twice per patient to be imaged and treated. For example, the microwave generator 202 may operate at the first power level for a period of time (which may be several seconds or even several minutes) during which a portion of the patient's body is imaged and then may be switched to operate at the second power level for a period of time (which may be several seconds or even several minutes) during which a treatment dose is delivered to a portion of the patient's body. The impedance network 401, 402, 403 may therefore be switched between the first and second impedances relatively infrequently. In such embodiments a vacuum or air relay switch may be capable of switching the impedance network 401, 402, 403 fast enough for its intended use.

In other embodiments the impedance network 401, 402, 403 may be switched between different states more frequently and a switch S which forms part of the impedance network 401, 402, 403 may be capable of switching between different states relatively quickly. For example, in some embodiments a microwave generator may provide microwaves for the generation of x-rays in order to image an imaging target at a plurality of different x-ray energies. In such embodiments it may be desirable to direct x-rays of different energies onto an imaging target within a relatively short period of time. For example, a single x-ray pulse having a first energy may be directed to be incident on an imaging target followed by a single x-ray pulse having a second energy. The microwave generator 202 may therefore switch between first and second power levels on a pulse-by-pulse basis and thus the impedance network 401, 402, 403 may be switched between different impedances on a pulse-to-pulse basis. In such embodiments the pulse frequency may be of the order of about 150 Hertz and thus the impedance network 401, 402, 403 may be switched between different impedances at a similar frequency. A relay switch such as a vacuum or air relay switch may not be capable of switching at such frequencies.

In some embodiments a switch S which forms part of an impedance network 401, 402, 403 may be capable of switching at higher frequencies than a relay switch. For example, at least one electronic switch such as a semiconductor switch. A semiconductor switch may, for example, comprise a solid state field effect transistor (FET) or an insulated-gate bipolar transistor (IGBT) may be used. A typical semiconductor switch such as a FET or IGBT is typically capable of operation at high frequencies and in particular may be capable of operation at frequencies of the order of about 100 Hertz or more. Other embodiments of an electronic switch may, for example, include a thyratron, tetrode and/or a triode.

Whilst semiconductor switches are typically capable of high frequency operation, a voltage which they are capable of withstanding before the switch breaks down may not be as high as a voltage which a vacuum or air relay switch can withstand. In some embodiments a stack of a plurality of semiconductor switches may be provided such that a voltage is shared between the stack of switches and the voltage to which each switch is exposed is reduced (when compared to using a single switch). In some embodiments, one or more semiconductor switches may be used in an arrangement of the type shown in FIG. 4B where a switch S provides a short circuit around one or more capacitors. In such arrangements a voltage to which the switch S is exposed may be less than in an arrangement of the type shown in FIGS. 4A and 4C where a switch S is arranged to connect and disconnect an electrical pathway.

In the embodiments shown in FIGS. 4A and 4B an impedance network is provided where the impedance network is switchable between a first and second impedance. Such an impedance network may be suitable for use in embodiments in which a microwave generator 202 operates only at a first and second power level. For example, in embodiments in which a microwave generator 202 operates at a first power level for medical imaging purposes and at a second power level for medical treatment purposes, an impedance network 203 which is switchable between first and second impedances suitable for the first and second power levels respectively may be used.

In some embodiments it may be desirable to operate a microwave generator 202 at three or more different power levels. For example, in embodiments in which x-rays are directed to be incident on an imaging target at a plurality of different x-ray energies it may be desirable to generate x-rays at three or more different energy levels. X-rays at each different energy level may excite different responses from materials being imaged. Increasing the number of energy levels used for imaging purposes may therefore improve the resolution of a resultant image and may improve the ability to distinguish between different objects. In such embodiments a microwave generator 202 may be capable of operating at three or more different power levels. An impedance network 203 may therefore be provided (such as the impedance network 403 shown in FIG. 4C) which is switchable so as to vary an impedance between three or more different impedance values such that a suitable impedance may be provided for each of the different power levels at which the microwave generator 202 is operated.

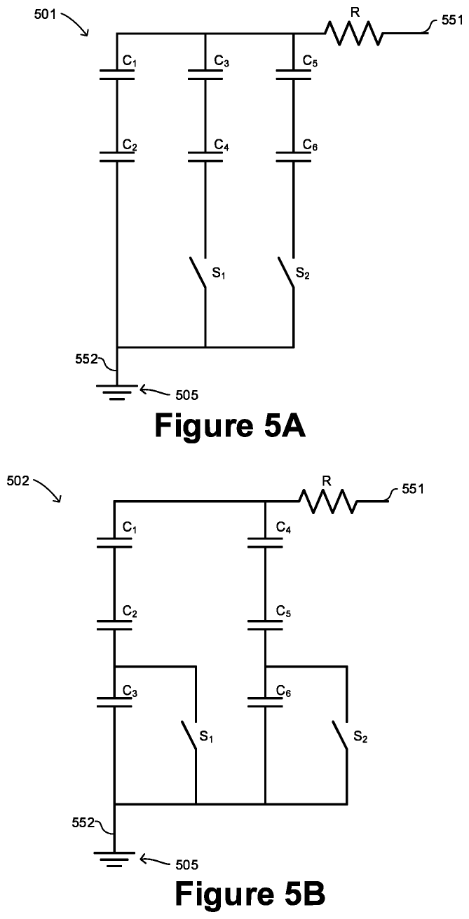

FIGS. 5A and 5B are schematic illustrations of impedance networks according to embodiments of the invention. A fourth embodiment of an impedance network 501 is shown in FIG. 5A and a fifth embodiment of an impedance network 502 is shown in FIG. 5B. The fourth embodiment 501 and the fifth embodiment 502 are suitable for use in a microwave generation system 200 as described above with reference to FIGS. 2A and 2B. Both the fourth 501 and fifth 502 embodiments are switchable so as to vary an impedance between three or more different impedance values.

Similarly to the embodiments shown in FIGS. 4A, 4B and 4C, both the fourth embodiment 501 and the fifth 502 embodiments of the impedance network include a first connection 551 and a second connection 552. The first connection 551 is suitable for connection to a transmission path extending between a pulse generator 201 and a microwave generator 203. For example, the first connection 551 may be connected to the transmission path 204 extending between the pulse generator 201 and the microwave generator 202 shown in FIGS. 2A and 2B. The second connection 552 is suitable for connection to electrical ground 505 as shown in FIGS. 5A and 5B. Both embodiments 501, 502 include a resistor R connected in between the first connection 551 and other components of the impedance network. The resistor R may provide a fixed resistance between the first connection 551 and other components of the impedance network 501, 502.

The fourth embodiment of the impedance network 501, which is shown in FIG. 5A, is similar to the first embodiment 401, which is shown in FIG. 4A, and the third embodiment 403 which is shown in FIG. 4C, since it includes a plurality of electrical pathways between the first 551 and second 552 connections, wherein at least one of the electrical pathways includes a switch operable to be opened and closed in order to disconnect and connect the pathway. The embodiment of FIG. 5A includes a first capacitor C₁ and a second capacitor C₂ provided in a first electrical pathway, a third capacitor C₃ and a fourth capacitor C₄ provided in a second electrical pathway, and a fifth capacitor C₅ and a sixth capacitor C₆ provided in a third electrical pathway. The second pathway includes a first switch S₁ and the third pathway includes a second switch S₂. The first switch S₁ and the second switch S₂ are operable to be opened and closed so as to disconnect and connect the second and third pathways respectively. The first switch S₁ and/or the second switch S₂ may be a relay switch (such as a vacuum or air relay switch) or an electronic switch such as a semiconductor switch.

The first S₁ and second S₂ switches provide four different switching combinations and may provide four different impedance values, if the series capacitance of the second and third pathways are different from each other. In some embodiments the capacitance of capacitors in different pathways may be different from each other. It may however, be desirable for each pathway to include capacitors having the same capacitance value such that the voltage across the pathway is shared relatively evenly down the pathway.

In one exemplary embodiment the first C₁ and second C₂ capacitors both have capacitances of about 1300 pF. The second C₂ and third C₃ capacitors may both have capacitances of about 700 pF. The third C₃ and fourth C₄ capacitors may both have capacitances of about 440 pF. In such an embodiment the four different switching combinations of the first S₁ and second S₂ switches result in total capacitances between the first 551 and second 552 connections of about 650 pF, 870 pF, 1000 pF and 1220 pF.

The fifth embodiment of the impedance network 502, which is shown in FIG. 5B, is similar to the second embodiment 402, which is shown in FIG. 4B, since it includes a plurality of capacitors connected between the first connection 551 and the second connection 552 and a switch connected across at least one of the capacitors, where the switch is operable to be opened and closed in order to disconnect and connect a short circuit around the at least one capacitor.

The embodiment of FIG. 5B includes a first capacitor C₁, a second capacitor C₂ and a third capacitor C₃ provided in a first electrical pathway, and a fourth capacitor C₄, a fifth capacitor C₅ and a sixth capacitor C₆ provided in a second electrical pathway. A first switch S₁ is connected across the third capacitor C₃ and a second switch S₂ is connected across the sixth capacitor C₆. The first switch S₁ and the second switch S₂ are operable to be opened and closed so as to disconnect and connect a short circuit around the third C₃ and sixth C₆ capacitors respectively. The first switch S₁ and/or the second switch S₂ may be a vacuum or air relay switch or an electronic switch such as a semiconductor switch.

The first S₁ and second S₂ switches provide four different switching combinations and may provide four different impedance values if the series capacitance of the first and second pathways are different from each other. In some embodiments the capacitance of capacitors in different pathways may be different from each other. It may however, be desirable for each pathway to include capacitors having the same capacitance value, such that the voltage across the pathway is shared relatively evenly down the pathway.

In one exemplary embodiment the first C1, second C₂ and third C₃ capacitors each have capacitances of about 1300 pF. The third C₃, fourth C₄ and fifth C₅ capacitors may each have capacitances of about 440 pF. In such an embodiment the four different switching combinations of the first S₁ and second S₂ switches result in total capacitances between the first 551 and second 552 connections of about 507 pF, 653 pF, 723 pF and 870 pF.

As was described above with reference to FIG. 4B, in the arrangement of FIG. 5B in which switches S₁, S₂ are connected across a capacitor, the switches S₁, S₂ may be exposed to a smaller voltage than the switches S₁, S₂ in the arrangement shown in FIG. 5A. Such an arrangement may therefore be suitable for use with a semiconductor switch which may have a smaller voltage rating than, for example, a vacuum or air relay switch.

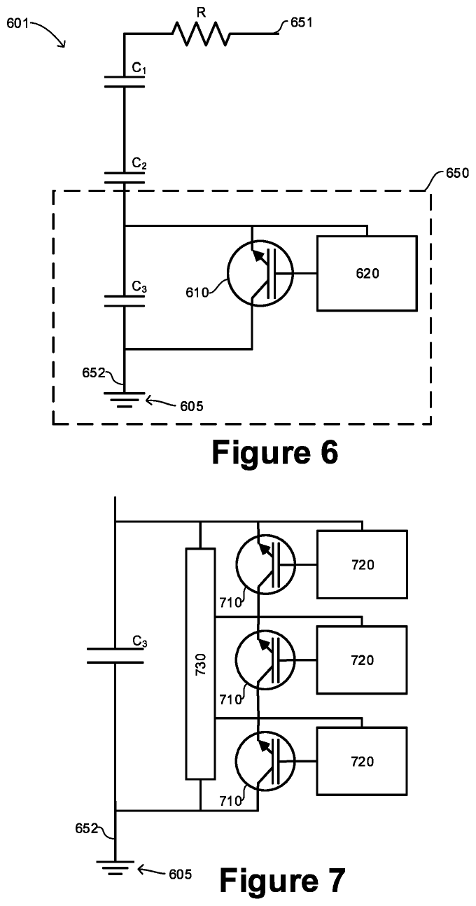

FIG. 6 is a schematic illustration of an impedance network 601 according to embodiments of the invention and which includes a semiconductor switch 610. The embodiment which is shown in FIG. 6 is similar to the embodiment of FIG. 4B and includes a first connection 651 for connection to a transmission path extending between a pulse generator 201 and a microwave generator 203 and a second connection 652 for connection to electrical ground 605. The impedance network 601 further includes a first capacitor C₁, a second capacitor C₂ and a third capacitor C₃. A switch 610 is connected across the third capacitor C₃ and is operable to be opened and closed so as to disconnect and connect a short circuit around the third capacitor C₃. The switch 610 is a semiconductor switch and may, for example, be a field effect transistor (FET) or insulated-gate bipolar transistor (IGBT). The switch 610 is controlled by a drive circuit 620, which may for example control a gate voltage so as to control the state of the switch 610. For example, the drive circuit 620 may be operable to change a gate voltage of the switch 610 so as to open and close the switch 610. Due to the relatively high voltages to which the switch 610 may be subjected, the drive circuit 620 may be floating (i.e. not connected to ground) and may be an independent circuit supplied with isolated control and power.

FIG. 7 is a schematic illustration of an alternative embodiment of a switching arrangement connected across a capacitor. The components shown in FIG. 7 may, for example, replace the components inside the dashed box 650 shown in FIG. 6. Components which are the same in FIGS. 6 and 7 are provided with the same reference numerals and will not be described again in connection with FIG. 7.

In the embodiment shown in FIG. 7 the switch across the capacitor C₃ is provided by a stack of three semiconductor switches 710. Each switch 710 is provided with a drive circuit 720 for independent control of the switches. Additional circuitry 730 is provided to share the voltage across the switches 730. By providing a stack of switches 710 as shown in FIG. 7, the total switching voltage is shared between the switches 710 so as to reduce the voltage to which each individual switch is exposed. Such an arrangement may be used when a total switching voltage exceeds a voltage rating of the individual switches to be used. Whilst a stack of three switches 710 is shown in FIG. 7, in other embodiments a stack of switches comprising fewer or more than three switches may be provided.

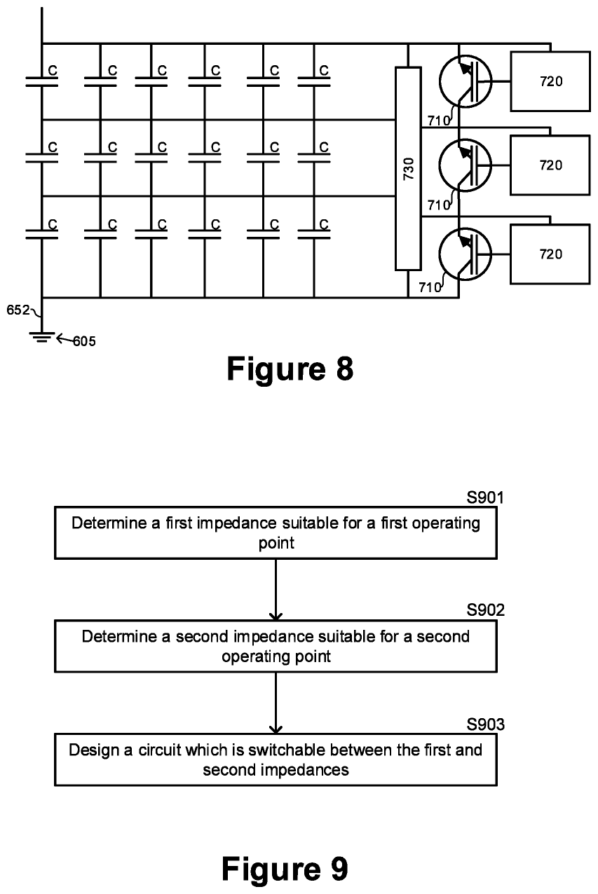

FIG. 8 is a schematic illustration of a further alternative embodiment of an arrangement suitable to provide a switched short circuit across a capacitance. The components shown in FIG. 8 may, for example, replace the components inside the dashed box 650 shown in FIG. 6. Components which are the same in FIGS. 6 and 8 are provided with the same reference numerals and will not be described again in connection with FIG. 8.

In the embodiment of FIG. 8 a capacitance is provided in the form of a plurality of capacitors C connected in a series and parallel combination. The plurality of capacitors C are electrically equivalent to the third capacitor C₃ in the embodiments of FIGS. 6 and 7. A stack of semiconductor switches 710 is connected across the capacitance provided by the capacitors C and is operable to be opened and closed so as to disconnect and connect a short circuit around the capacitance.

Providing a capacitance in the form of a plurality of capacitors connected in a series and parallel combination allows the individual capacitors to be of a lower voltage rating than if the capacitance is provided by a single capacitor C₃, since each individual capacitor is exposed to a lower voltage. The use of lower voltage rating capacitors may reduce the overall expense of providing a capacitance, since capacitors of a lower voltage rating tend to be available at a cheap cost when compared to capacitors of a higher voltage rating. Whilst a specific example has been described in which a capacitance with a switching arrangement connected across it, is provided in the form of a plurality of capacitors connected in a series and parallel combination, a similar arrangement of a plurality of capacitors may be used to realise any desired capacitance in an impedance network. For example, any of the capacitors described in connection with the embodiments shown in FIGS. 4, 5, 6 and 7 may be realised in the form of an arrangement of a plurality of capacitors.

In some embodiments, one or more components of an impedance network may be provided on a printed circuit board (PCB). For example, at least part of the embodiment shown in FIG. 8 may be provided on one or more PCBs.

Several embodiments of a switching network according the invention have been described above. Any components or arrangements included in the embodiments may be combined with any components or arrangement included in other embodiments. For example, an impedance network may include a plurality of electrical pathways including one or more capacitors and at least one switch arranged to connect and disconnect at least one of the pathways (as shown in FIGS. 4A and 5A) and may further include a switch connected across at least one capacitor so as to provide a switchable short circuit around the capacitor (as shown in FIGS. 5B, 6, 7 and 8). An impedance network may include a plurality of capacitors and a switch arranged such that when the switch is open a first subset of the capacitors is connected across a pulse generator 201 and when the switch is closed a second subset of the capacitors is connected across the pulse generator 201.

As has been described above, an impedance network may be switchable between two or more impedance values suitable for use at different operating points of a microwave generator 203. For a given application, operating points of a microwave generator which will be needed during use may be known in advance. For example, in applications in which a microwave generator is switched between a first operating point suitable for the generation of microwaves for medical imaging purposes and a second operating point suitable for the generation of microwaves for medical treatment purpose, the first operating point and the second operating point may be set and known in advance of use. Similarly in applications in which a microwave generator is switched between a plurality of different operating points for exciting different responses in an imaging target, the different operating points may be set and known in advance. Consequently an impedance network may be designed for use at a plurality of different operating points.

FIG. 9 is a flowchart illustrating a method of design of an impedance network in accordance with an embodiment of the invention. The impedance network is for use in a microwave generation system comprising a pulse generator 201 and a microwave generator 202. At step 901 of the method, a first impedance is determined. The first impedance is suitable for connection across the pulse generator when the microwave generator operates at a first operating point. The first operating point of the microwave generator may represent an operating point to be used in a given application. For example, the first operating point may represent an operating point to be used for medical imaging purposes.

The first impedance may be an impedance which substantially matches the impedance of the microwave generator 202 to the impedance of the pulse generator at the first operating point of the microwave generator 202. The first impedance may be determined based on experimental observations of an impedance which results in stable operation of a microwave generator 202 at the first operating point. Additionally or alternatively, the first impedance may be determined based on modelling and/or calculation of an impedance suitable for use at the first operating point.

At step 902, a second impedance is determined. The second impedance is suitable for connection across the pulse generator 201 when the microwave generator 202 operates at a second operating point. The second operating point of the microwave generator 202 may represent an operating point to be used in a given application. For example, the second operating point may represent an operating point to be used for medical treatment purposes.

The second impedance may be an impedance which substantially matches the impedance of the microwave generator 202 to the impedance of the pulse generator 201 at the second operating point of the microwave generator 202. The second impedance may be determined based on experimental observations of an impedance which results in stable operation of a microwave generator 202 at the second operating point. Additionally or alternatively, the second impedance may be determined based on modelling and/or calculation of an impedance suitable for use at the second operating point.

At step 903 a circuit is designed which is switchable between the first and second impedances. The circuit may be suitable for connection between a transmission path extending between the pulse generator 201 and the microwave generator 203 and electrical ground. The circuit is switchable between a first state in which an impedance between the transmission path and electrical ground is substantially the first impedance and a second state in which the impedance between the transmission path and electrical ground is substantially the second impedance. The circuit may, for example, include a plurality of electrical pathways and at least one switch operable to be opened and closed in order to disconnect and connect at least one of the pathways. The pathways may each include one or more capacitors, and opening and closing the at least one switch may change a capacitance provided between the transmission path and electrical ground. Additionally or alternatively the electrical circuit may comprise at least one switch connected across at least one capacitor. The switch may be operable to be opened and closed in order to disconnect and connect a short circuit around the at least one capacitor so as to change a capacitance between the transmission path and electrical ground. The circuit may include a plurality of capacitors and a switch arranged such that when the switch is open a first subset of the capacitors is connected and when the switch is closed a second subset of the capacitors is connected. The circuit may include one or more components and/or arrangements of components as described above with reference to FIGS. 4-8.

Whilst a method of design has been described above in which an impedance network is designed which is switchable between a first and second impedance, the method may be extended to an impedance network which is switchable between three or more impedance values for use at three or more different operating points of a microwave generator 202. An impedance network designed according to the method of design may be manufactured according to the design.

Embodiments of a microwave generation apparatus 200 including an impedance network 203 have been described above in the context of generating microwaves for driving a particle accelerator 103. As was mentioned above, a particle accelerator 103 driven by a microwave generation apparatus 200 may find applications for example, in medical imaging and/or treatment and in imaging of concealed objects, such as cargo.

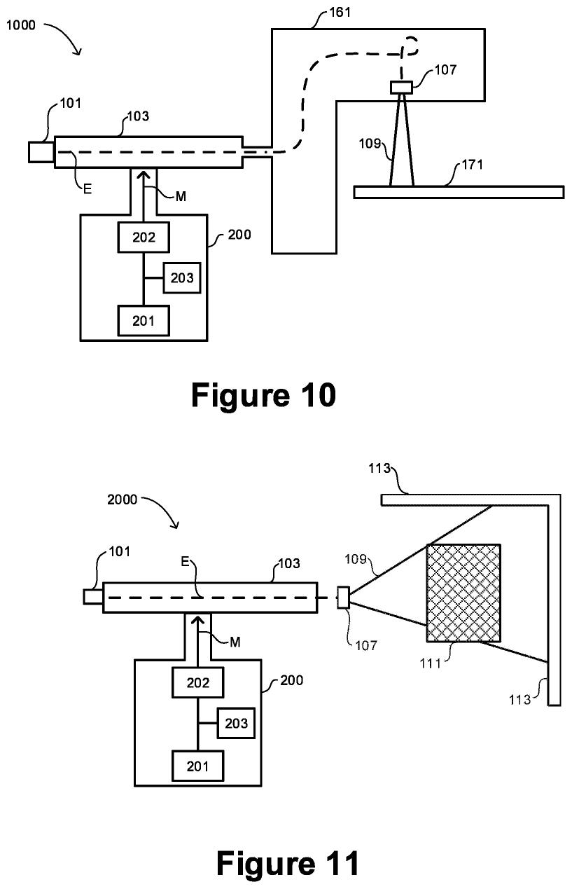

FIG. 10 is a schematic illustration of a radiotherapy system 1000 including a microwave generation system 200 according to an embodiment of the invention. As was explained in detail above, the microwave generation system 200 comprises a pulse generator 20, a microwave generator 202 and an impedance network 203. The microwave generator 202 emits microwaves M which are provided to an electron accelerator 103 (which may, for example, be a LINAC). An electron source 101 emits electrons E which pass through the accelerator 103. At least some of the energy associated with the microwaves M is used to accelerate the electrons E. The electrons E are guided by an electron beam transport system 161, which may, for example, comprise one or more steering magnets arranged to steer the path of the electrons E.

The electrons E are guided to be incident on a target material 107 (which may, for example, comprise a tungsten target) which causes some of the energy of the electrons E to be emitted as x-rays 109 from the target material. The radiotherapy system 1000 is arranged such that x-rays 109 are directed towards a treatment table 171 on which a patient may be situated, such that the x-rays 109 are incident on at least a part of the patient's body.

As was explained above, x-rays 109 may be directed to be incident on a patient's body for imaging and/or treatment purposes. For example, relatively low power x-rays 109 may initially be directed to be incident on part of a patient's body in order to image the patient's body and determine a position at which a radiotherapy treatment dose of x-rays 109 should be administered. Relatively high power x-rays 109 may then be generated and directed onto the part of the patient's body which has been identified for treatment so as to deliver a radiotherapy treatment to the patient.

As was described extensively above, the power of the x-rays 109 generated by the radiotherapy system 1000 may be varied by varying the power of the microwaves M generated by the microwave generation system 200, so as to vary the energies to which the electrons E are accelerated to in the accelerator 103. The switchable impedance network 203 allows for stable operation of the microwave generation system 100 at a plurality of different operating points so as to allow the power of the generated microwaves M to be varied.

Whilst in the embodiment which is shown in FIG. 10, the electrons E are directed to be incident on a target material 107 so as to generate x-rays 109, in some embodiments the electrons E themselves may be used for treatment purposes. For example, the target material 107 may be removed from the path of the electrons E and the electrons E may be directed to be incident on a part of a patient's body so as to deliver a radiotherapy treatment dose.

FIG. 11 is a schematic illustration of a cargo scanning system 2000 including a microwave generation system 200 according to an embodiment of the invention. The microwave generation system 200 comprises a pulse generator 20, a microwave generator 202 and an impedance network 203. Similarly to the embodiment shown in FIG. 10, the microwave generator 202 emits microwaves M which are provided to an electron accelerator 103 (which may, for example, be a LINAC). An electron source 101 emits electrons E which pass through the accelerator 103. At least some of the energy associated with the microwaves M is used to accelerate the electrons E.

The electrons E are directed to be incident on a target material 107 (which may, for example, comprise a tungsten target) which causes some of the energy of the electrons E to be emitted as x-rays 109 from the target material. The cargo scanning system 2000 is arranged such that the x-rays 109 are directed to be incident on an imaging target 111, which may for example comprise a container in which cargo is stored.

At least one radiation sensor 113 is arranged to detect x-ray radiation which is transmitted through the imaging target 111. The intensity and position of x-ray radiation incident on the radiation sensor 11 may be used to form an image of the imaging target 111, which resolves the internal structure of the imaging target 111. The imaging target 111 may, for example, be moved relative to the cargo scanning system 2000 so as to scan the imaging target and form one or more images of different parts of the imaging target 111. For example, the imaging target 111 may be moved into and/or out of the page of FIG. 11 so as to image different portions of the imaging target 111. Alternatively at least part of the cargo scanning system 2000 may be moved relative to the imaging target so as to image different portions of the imaging target 111.

As was described above, the transparency and/or reflectivity of a material to x-rays of varying energy may be different for different materials. The imaging target 111 may therefore be imaged using x-rays of varying energy so as to allow different materials which form the imaging target 111 to be more effectively resolved, when compared to imaging the target using x-rays of a single energy. The use of x-rays of variable energy to image a target may allow concealed objects in the target to be more effectively resolved and identified.

The power of the x-rays 109 generated by the cargo scanning system 2000 may be varied by varying the power of the microwaves M generated by the microwave generation system 200, so as to vary the energies to which the electrons E are accelerated to in the accelerator 103. The switchable impedance network 203 allows for stable operation of the microwave generation system 100 at a plurality of different operating points so as to allow the power of the generated microwaves M to be varied.

Whilst embodiments have been described above in which a microwave generation system 200 is used to drive a particle accelerator 103, a microwave generation system 200 as described herein may find other applications than those specifically described herein.

All ranges and values (e.g. values and/or ranges of power and/or frequency) provided herein are provided for illustrative purposes only and should not be interpreted to have any limiting effect.

Features, integers or characteristics described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

1. A microwave generation system comprising:
a microwave generator;
a pulse generator arranged to provide pulses of electrical power to the microwave generator, wherein the pulse generator is operable to vary the power of the pulses of electrical power which are provided to the microwave generator; and
an impedance network connected between the pulse generator and the microwave generator, wherein the impedance network is switchable so as to substantially match an impedance across the pulse generator according to variations in the impedance of the microwave generator.

2. The microwave generation system of claim 1, wherein the microwave generation system includes a transmission path extending between the pulse generator and the microwave generator and wherein the impedance network is connected between the transmission path and electrical ground.

3. The microwave generation system of claim 2, wherein the impedance network is arranged to provide a plurality of electrical pathways between the transmission path and electrical ground, wherein at least one of the electrical pathways includes a switch operable to be opened and closed so as to disconnect and connect the pathway so as to vary the impedance between the transmission path and electrical ground.

4. The microwave generation system of claim 3, wherein the impedance network includes a plurality of capacitors and a switch arranged such that when the switch is open a first subset of the capacitors is connected across the pulse generator and when the switch is closed a second subset of the capacitors is connected across the pulse generator.

5. The microwave generation system of claim 3 or 4, wherein the impedance network includes a plurality of capacitors connected between the transmission path and electrical ground and a switch connected across at least one of the capacitors, wherein the switch is operable to be opened and closed in order to disconnect and connect a short circuit around the at least one capacitor.

6. The microwave generation system of any of claims 2-5, wherein the transmission path includes a pulse transformer and/or inductive adder.

7. The microwave generation system of claim 6, wherein the impedance network is connected to the transmission path between the microwave generator and the pulse transformer and/or inductive adder.

8. The microwave generation system of claim 6, wherein the impedance network is connected to the transmission path between the pulse generator and the pulse transformer and/or inductive adder.

9. The microwave generation system of any preceding claim, wherein the microwave generator includes a magnet.

10. The microwave generation system of claim 9, wherein the magnet comprises a permanent magnet.

11. The microwave generation system of claim 9, wherein the magnet comprises an electromagnet operable to vary a magnetic field strength of the electromagnet so as to vary the power of microwaves generated by the microwave generator.

12. The microwave generation system of any of claims 9-11, wherein the impedance network is arranged to vary the impedance across the pulse generator in response to a variation in the magnetic field strength of the magnet.

13. The microwave generation system of any preceding claim, wherein the impedance network includes at least one electronic switch operable to be opened and closed so as to vary the impedance across the pulse generator.

14. The microwave generation system of claim 13, wherein the at least one electronic switch comprises a semiconductor switch.

15. The microwave generation system of any preceding claim, wherein the impedance network includes at least one relay switch operable to be opened and closed so as to vary the impedance across the pulse generator.

16. The microwave generation system of any preceding claim, wherein the microwave generator is operable to generate microwaves having a first output power in response to receiving pulses of electrical power having a first input power and to generate microwaves having a second output power in response to receiving pulses of electrical power having a second input power.

17. The microwave generation system of claim 16, wherein the microwaves having the first output power are suitable for driving an electron accelerator to accelerate electrons for generation of x-rays having a power suitable for medical imaging purposes.

18. The microwave generation system of claim 16 or 17, wherein the microwaves having the second output power are suitable for driving an electron accelerator to accelerate electrons having a power suitable for medical treatment purposes.

19. The microwave generation system of any preceding claim, wherein the impedance network is switchable so as to vary an impedance across the pulse generator between three or more different impedance values.

20. The microwave generation system of any preceding claim, wherein the wherein the microwave generator is operable to generate microwaves suitable for driving an electron accelerator to accelerate electrons for generation of x-rays.

21. A microwave generation apparatus comprising:
a microwave generator arranged to receive pulses of electrical power from a pulse generator and use the received power to generate microwaves; and
an impedance network arranged to provide an impedance across the pulse generator, wherein the impedance network is switchable so as to vary the impedance across the pulse generator according to variation in the power of the pulses of electrical power received from the pulse generator.

22. A pulse generation apparatus comprising:
a pulse generator arranged to output pulses of electrical power to a microwave generator; and
an impedance network arranged to provide an impedance across the pulse generator, wherein the impedance network is switchable so as to vary the impedance between across the pulse generator according to a variation in the power of the pulses of electrical power output from the pulse generator.

23. An impedance network suitable for use in the microwave generation system of claims 1-20, the microwave generation apparatus of claim 21 or the pulse generation apparatus of claim 22.

24. The impedance network of claim 23, wherein the impedance network is switchable between a first impedance suitable for a first operating point of the microwave generator and a second impedance suitable for a second operating point of the microwave generator, wherein the first impedance substantially matches the impedance of the microwave generator to the impedance of the pulse generator at the first operating point of the microwave generator and the second impedance substantially matches the impedance of the microwave generator to the impedance of the pulse generator at the second operating point of the microwave generator.

25. An impedance network for a microwave generating system, the impedance network comprising:
a first connection for connection to a transmission path extending between a pulse generator and a microwave generator;
a second connection for connection to electrical ground;
a plurality of capacitors arranged between the first connection and the second connection; and
at least one switch arranged to switch at least one of the plurality of capacitors into and out of an electrical pathway between the first connection and the second connection so as to change an impedance between the first connection and the second connection.

26. The impedance network of claim 25, wherein the at least one switch comprises at least one electronic switch.

27. The impedance network of claim 24 or 25, wherein the at least one switch comprises at least one relay switch.

28. An electron acceleration system comprising:
a microwave generation system according to any of claims 1-20; and
an electron accelerator comprising at least one resonant structure arranged to receive electrons from an electron source such that the electrons pass through the resonant structure, wherein the electron accelerator is arranged to receive microwaves generated by the microwave generation system such that the received microwaves establish accelerating electromagnetic fields in the resonant structure, the accelerating electromagnetic fields being suitable for accelerating the electrons travelling through the resonant structure.

29. An x-ray generator comprising:
an electron acceleration system according to claim 28; and
a target material arranged to receive accelerated electrons output from the electron accelerator and generate x-rays.

30. An x-ray imaging system comprising:
an x-ray generator according to claim 29 operable to direct generated x-rays to be incident on an imaging target; and
at least one sensor arranged to detect x-rays transmitted by and/or reflected from the imaging target.

31. A radiotherapy system including a microwave generation system according to any of claims 1-20, a microwave generation apparatus according to claim 21, a pulse generation apparatus according to claim 22, a impedance network according to any of claims 23-27, an x-ray generator according to claim 29 or an x-ray imaging system according to claim 30.

32. A cargo scanning system including a microwave generation system according to any of claims 1-20, a microwave generation apparatus according to claim 21, a pulse generation apparatus according to claim 22, a impedance network according to any of claims 23-27, an x-ray generator according to claim 29 or an x-ray imaging system according to claim 30.

33. Apparatus according to any preceding claim, wherein the microwave generator comprises a magnetron.

34. A method of generating microwaves, the method comprising:
outputting pulses of electrical power at a pulse generator and providing the pulses of electrical power to a microwave generator so as to cause generation of microwaves at the microwave generator;
varying the power of the pulses of electrical power provided to the microwave generator in order to vary the power of the microwaves output by the microwave generator; and
varying an impedance across the pulse generator so as to substantially match the impedance across the pulse generator in accordance with a variation in the impedance of the microwave generator.
